(19) United States
(12) Patent Application Publication
(10) Pub. No.: US 2014/0339437 A1
(43) Pub. Date: Nov. 20, 2014

(54) METHOD AND APPARATUS FOR SENSING DEVICE INCLUDING QUANTUM DOT LIGHT EMITTING DEVICES

(71) Applicant: Hany Maher AZIZ, Oakville (CA)

(72) Inventor: Hany Maher AZIZ, Oakville (CA)

(21) Appl. No.: 14/278,711

(22) Filed: May 15, 2014

Related U.S. Application Data
(60) Provisional application No. 61/855,516, filed on May 17, 2013.

(51) Int. Cl. H01L 51/50; G01N 21/64

(52) U.S. Cl. CPC H01L 51/502; G01N 21/64; H01L 51/5056; H01L 51/5072; G01N 2201/0628
USPC 250/458.1; 257/13

(57) ABSTRACT

The disclosure is directed at a sensing apparatus which includes a light emitting device including quantum dot light emitting diodes. The light emitting device transmits light towards a sample of interest to assist the sensing apparatus in determining if a target material is present or absent within the sample of interest.

### CROSS-REFERENCE TO RELATED APPLICATIONS

This application claims the benefit of priority of U.S. Provisional Patent Application No. 61/855,516 filed May 17, 2013, which is hereby incorporated by reference.

### FIELD OF THE DISCLOSURE

The disclosure is generally directed at chemical and biological sensing application and more specifically at a method and apparatus for a sensing device including quantum dots light emitting devices.

### BACKGROUND OF THE DISCLOSURE

There is a growing interest in developing portable and/or low cost chemical and biological sensing apparatus for various applications including medical, environmental, health & safety and industrial applications. This has been the main driver behind the interest in developing miniature and “chip-based” technologies such as Lab-on-a-Chip, where spectroscopic detection is carried out on a sample utilizing a microfluidic system or a surface with certain chemical selectivity.

Chemical and biological sensors are devices that are capable of detecting the presence of certain chemical or biological species. The sensing functionality of these devices is often based on the spectroscopic method, where electromagnetic radiation, such as optical, UV or IR radiation typically in the 200-2000 nm range, from an illumination source irradiates the chemical or biological sample of interest, leading to the excitation of certain chromophores that are characteristic of a target material or material of interest. A detector is used to detect the resulting luminescence (usually fluorescence or phosphorescence) from the chromophores, thereby determining the presence (or absence) of the material of interest within different mediums.

Good light coupling between the sample handling component (e.g. the microfluidic sensitive or the sensitive surface) and each of the excitation and detection devices is essential for increasing the signal/noise ratio, and hence the sensor sensitivity. Towards this end, there is a strong interest in using organic light emitting devices (OLEDs) for the excitation components since they are uniquely capable of being monolithically integrated on the same chip due to their easy and room temp. processing capabilities, hence they can provide improved optical coupling into the chip. OLEDs however have a relatively wide electroluminescence spectrum (where the full width at half maximum is larger than 50 nm), and the “spectral overlap” makes it difficult to resolve sample luminescence from that of the OLED. This issue has been described in a number of scientific publications. Past attempts to overcome the spectral overlap issue utilized timing-based signal processing techniques, which is quite complex.

There is therefore a need to develop alternative excitation sources that can still be monolithically integrated on the same chip, yet do not have the spectral-overlap limitations of conventional OLEDs.

Therefore, there is provided a novel quantum dot light emitting device for chemical and biological sensing applications.

### SUMMARY OF THE DISCLOSURE

The disclosure is directed at a light emitting device which uses quantum dot-based light emitting diodes (QD-LEDs) as an excitation source in spectroscopic-based sensing devices including, but not limited to, Lab-on-a-Chip chemical and biological sensors. The narrow electroluminescence (EL) spectra of quantum dot materials (full width at half maximum (FWHM) less than 50 nm) has the potential to reduce the spectral overlap issue referred to above, and are therefore more suitable for spectroscopic-based sensing applications. QD-LEDs, including those utilizing organic semiconductor materials for electron and/or hole transport, usually referred to as QD-OLEDs, can also be used for this purpose. Various quantum dot materials such as those with peak emission in the green, blue, or UV can be particularly useful for certain applications and within certain sensing devices. Although in general any luminescent quantum dot material can be used for this disclosure, those based on a core/shell morphology, including materials selected from III-V and II-VI compounds for the core and the shell, and, optionally, further containing organic groups attached to the shell, may be more suitable for certain applications due to their high colour purity, high luminescent quantum yield, and/or solubility are preferred. The shell material typically has a wider bandgap than the core material. For example, in a preferred embodiment, the core material can include Cadmium Selenide (CdSe), Cadmium Sulfide (CdS) or Zinc Selenide (ZnSe) and the shell material is selected from CdS, Cadmium Zinc (CdZn) or Zinc Sulfide (ZnS). It would be understood that other like materials are also contemplated.

In one aspect of the disclosure, there is provided a light emitting device including a first electrode; a light emitting region including quantum dots; and a second electrode; wherein the device is used for producing fluorescence from a material.

### BRIEF DESCRIPTION OF THE DRAWINGS

Embodiments of the present disclosure will now be described, by way of example only, with reference to the attached Figures.

FIG. 1 is a schematic diagram of a first embodiment of a light emitting device using quantum dot light emitting diodes (QD-LEDs) for use with a sensing device;

FIG. 2 is a schematic diagram of a second embodiment of a light emitting device using QD-LEDs for use with a sensing device;

FIG. 3 is a schematic diagram of a third embodiment of a light emitting device using QD-LEDs for use with a sensing device;

FIG. 4 is a schematic diagram of a fourth embodiment of a light emitting device using QD-LEDs for use with a sensing device;

FIG. 5a is a schematic diagram of a fifth embodiment of a light emitting device using QD-LEDs for use with a sensing device;

FIG. 5b is a schematic diagram of a sixth embodiment of a light emitting device using QD-LEDs for use with a sensing device;

FIG. 5c is a schematic diagram of a seventh embodiment of a light emitting device using QD-LEDs for use with a sensing device; and

FIG. 6 is a schematic diagram of a sensing device.

### DETAILED DESCRIPTION

The disclosure is directed at a sensing device which includes a light emitting device having quantum dot light emitting diodes (QD-LEDs). In one embodiment, the light emitting device is used as an excitation source for producing a fluorescence light for chemical and biological sensing applications.

In order to assist the reader with respect to terminology, the term “layer” indicates a single coating generally having a composition that differs from the composition of an adjacent layer. The term “region” refers to a single layer or a plurality of adjacent layers. The phrase “light-emitting device” refers to any device that includes one or more layers having any material that is interposed between at least two electrodes, and which is capable of emitting light by electroluminescence when an electrical potential difference (voltage) is applied across the electrodes. The phrase “quantum dots” refer to small particles of a characteristic dimension such as an average diameter of from about, but not limited to, 1 nm and to about 50 nm. The particles are preferably a material made of a compound of group III and group V or a compound of group II and group VI elements of the periodic table of elements, such as, for example, Cadmium Selenium (CdSe), Cadmium Sulfide (CdS), Zinc Selenium (ZnSe), Cadmium Sulfide (CdS), Cadmium Zinc (CdZn), Zinc Sulfide (ZnS), Indium Phosphide (InP), Indium Arsenide (InAs) or Cadmium Selenium Sulfide (CdSeS), and wherein the particles are capable of producing light.

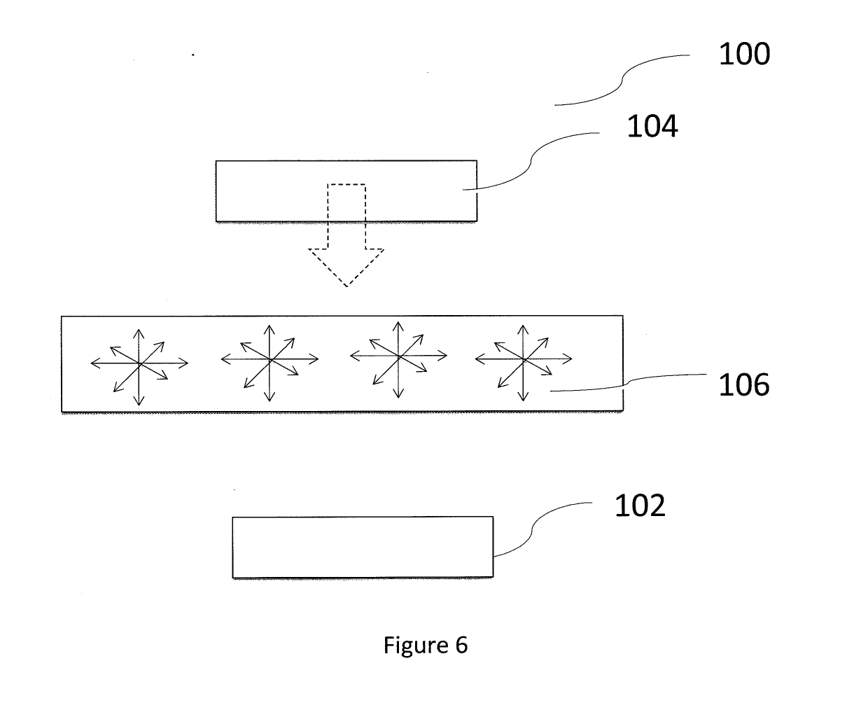

Turning to FIG. 6, a schematic diagram of a sensing device is shown. The sensing device 100 include a sensor apparatus 102 along with a light emitting device 104. The light emitting device, which includes QD-LEDs, acts as an excitation source for assisting in the determination of the presence or absence of a target material within a sample of interest 106. The sensor apparatus 102 includes devices and components for sensing the resulting luminescence from the interaction between the light emitting device 104 and the sample of interest 106 and then processing the results to determine the presence or absence of the target material within the sample of interest. The target material may be a gas, a liquid or a material which is within a liquid.

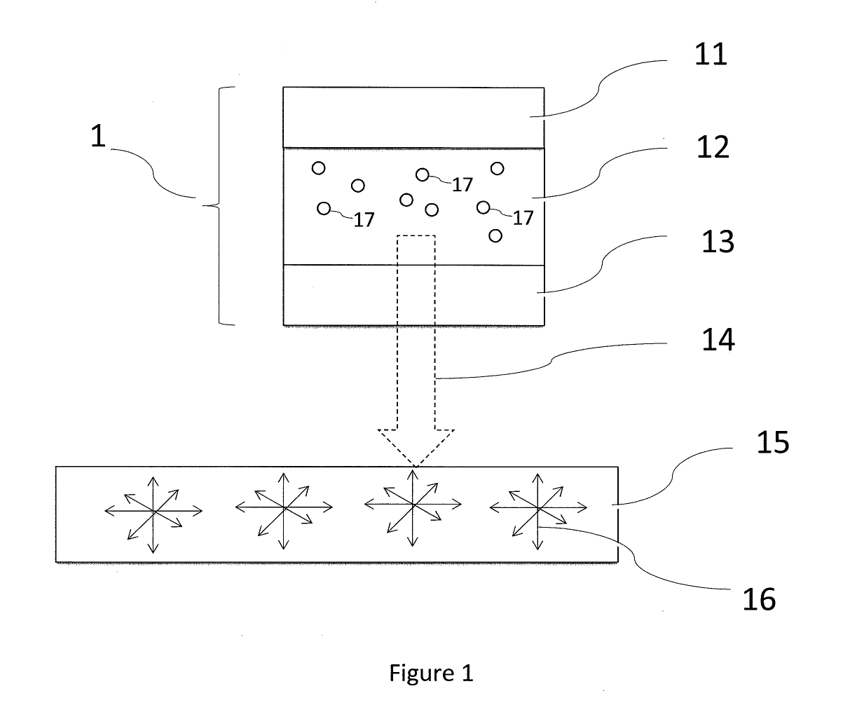

Turning to FIG. 1, a first exemplary embodiment of a light emitting device for use with the sensing device is shown. A sensing device light emitting device 1 includes a first electrode 11, a light emitting region 12 including quantum dots 17, and a second electrode 13, and wherein the application of a voltage between the first electrode 11 and the second electrode 13 leads to the emission of light (seen as arrow 14) from the device 1. The light 14 is directed at a sample of interest 15 that is capable of receiving the emitted light 14 and, in response, producing fluorescence light shown as arrows 16. This fluorescence light is then sensed by the sensing apparatus as shown in FIG. 6 to determine the presence or absence of a target material.

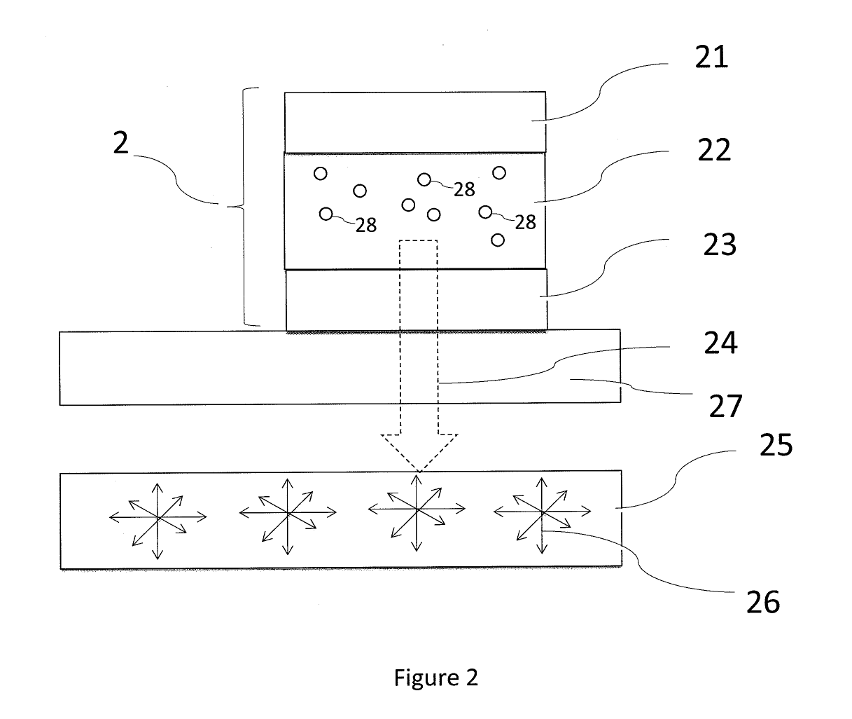

Turning to FIG. 2, a second exemplary embodiment of a light emitting device is shown. A light emitting device 2 includes a first electrode 21, a light emitting region 22 having quantum dots 28, a second electrode 23, and a substrate 27. As would be understood, since QD-LEDs are thin film devices the substrate may act as a support for the light emitting region The application of a voltage between the first electrode 21 and the second electrode 23 leads to the emission of light 24 from the device directed at a sample of interest 25 that is capable of receiving the emitted light 24 and, in response, producing fluorescence light 26 which may be then sensed to determine the presence of absence of a target material. The substrate 27 can be made of any suitable material that does not obstruct the emitted light 24 from reaching the sample of interest 25. The substrate 27 can alternatively be located adjacent to the first electrode 21 instead of the second electrode 23. In this case the substrate 27 is not in the path of the emitted light 24.

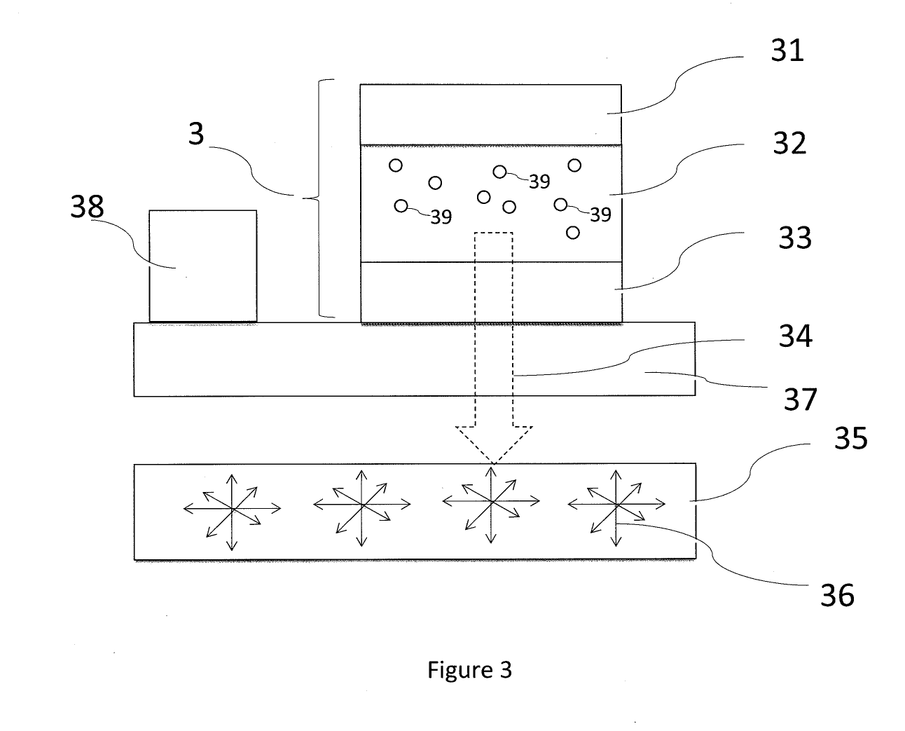

A third exemplary embodiment of a light emitting device is seen in FIG. 3 wherein a light emitting device 3 includes a first electrode 31, a light emitting region 32 having quantum dots 39, a second electrode 33, and a substrate 37, and wherein the application of a voltage between the first electrode 31 and the second electrode 33 leads to the emission of light 34 from the device directed towards a sample of interest 35 that is capable of receiving the emitted light 34 and, in response, producing fluorescence light 36 for a sensing apparatus to determine the presence of absence of a target material. The substrate 37 can be made of any suitable material that does not obstruct the emitted light 34 from reaching the sample of interest 35. A light sensor 38 capable of detecting the fluorescence 36 is located adjacent to the substrate.

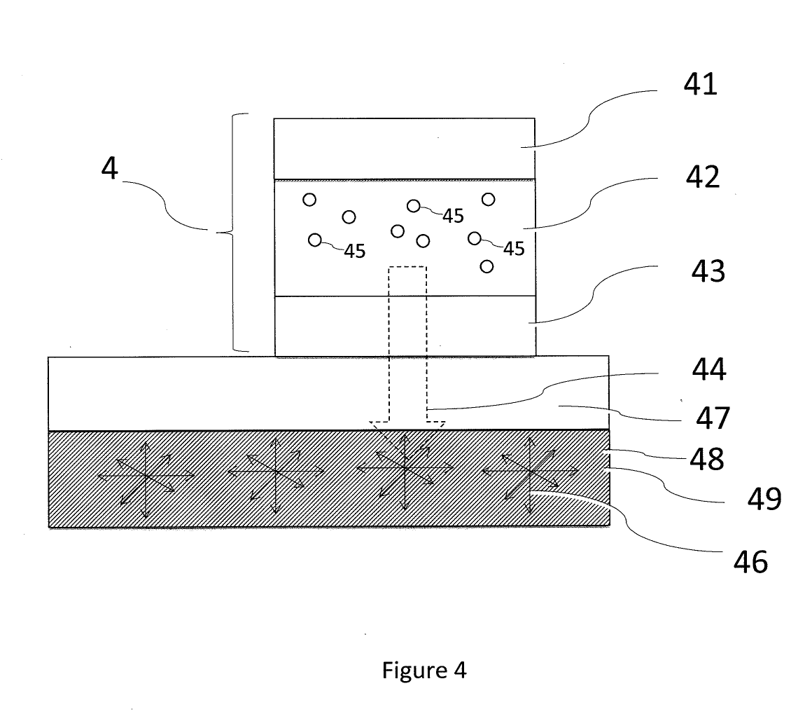

A fourth exemplary embodiment of a light emitting device is seen in FIG. 4 wherein a light emitting device 4 includes a first electrode 41, a light emitting region 42 having quantum dots 45, a second electrode 43, and a substrate 47, and wherein the application of a voltage between the first electrode 41 and the second electrode 43 leads to the emission of light 44 from the device and wherein there exists a container 49 which contains a sample of interest 48. The container 49 is placed adjacent to the substrate 47. The sample of interest 48 in the container 49 is capable of receiving the emitted light 44 and, in response, producing fluorescence light 46 for the determination of the presence or absence of a target material within the sample of interest 48. The substrate 47 and the container 49 can be made of any suitable materials that do not obstruct the emitted light 44 from reaching the sample of interest 48. The container 49 can be of any form suitable for holding the sample of interest 48. For example it can be a tube, a microchannel, or a prorous material capable of carrying the sample of interest 48.

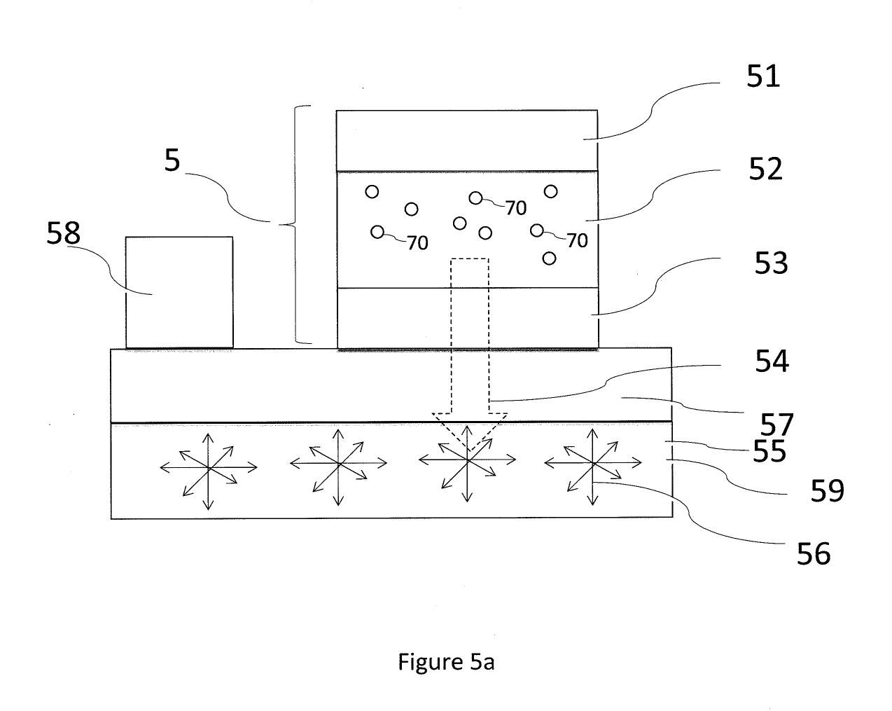

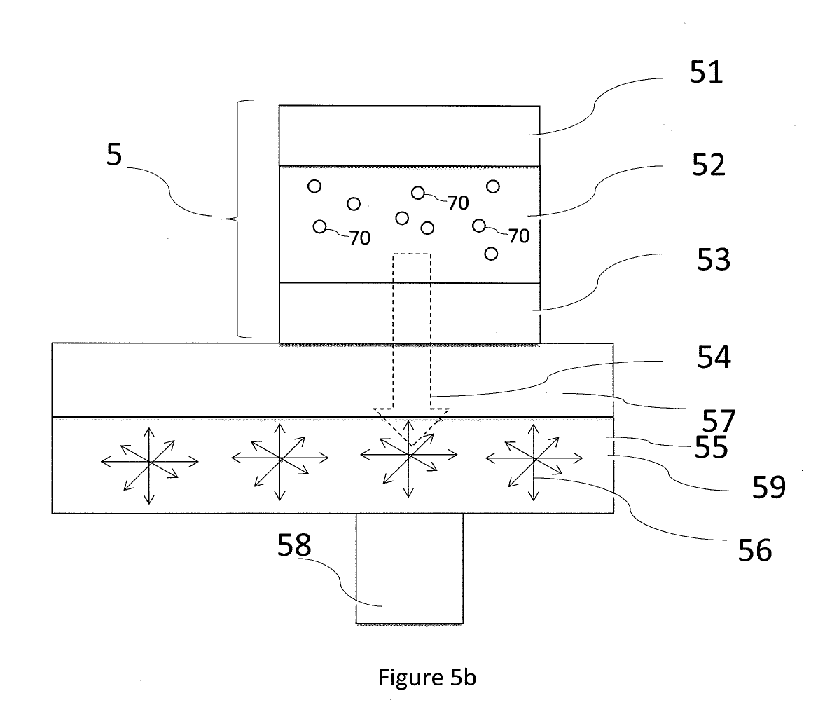

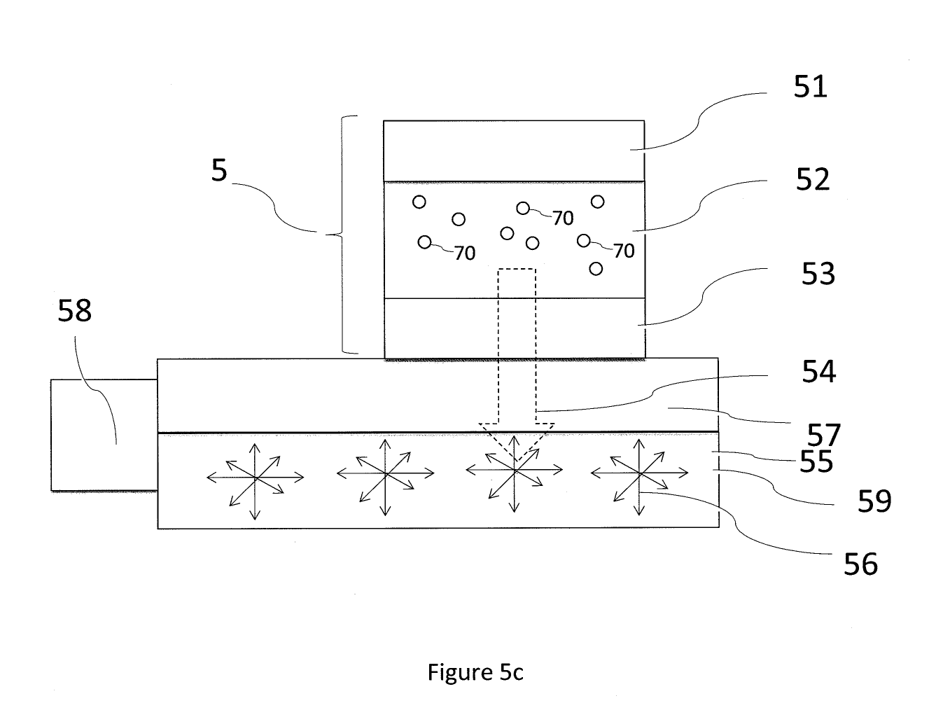

A fifth exemplary embodiment of this disclosure is seen in FIGS. 5a to 5c, wherein a light emitting device 5 includes a first electrode 51, a light emitting region 52 having quantum dots 70, a second electrode 53, and a substrate 57, and wherein the application of a voltage between the first electrode 51 and the second electrode 53 leads to the emission of light 54 from the device and wherein there exists a container 59 which contains a sample of interest 55 that is capable of receiving the emitted light 54 and, in response, producing fluorescence light 56 for the termination of a presence or absence of a target material within the sample of interest 55. In the current embodiment, the container 59 is placed adjacent to the substrate 57. The substrate 57 and the container 59 can be made of any suitable materials that do not obstruct the emitted light 54 from reaching the sample of interest 55. The container 59 can be of any form suitable for holding the sample of interest 55. For example it can be a tube, a microchannel, or a prorous material capable of carrying the sample of interest. A light sensor 58 capable of detecting the fluorescence 56 is located adjacent to the substrate (FIG. 5a). Alternatively, the light sensor 58 is located adjacent to the container 59 (FIG. 5b) or adjacent the container 59 and substrate 57. Of course other locations for the light sensor 58 are also possible.

In operation, due to the presence of the QD-LEDS within the light emitting regions, the spectrum of the fluorescence light 16, 26, 36, 46 or 56 is different from the spectrum of the emitted light 14, 24, 34, 44 or 54. In embodiments, the majority of the fluorescent light occurs at a wavelength longer the wavelength at which the majority of the emitted light 14, 24, 34, 44 or 54 occurs. This is intrinsic to fluorescence characteristics. Due to this, the sensing apparatus may more easily determine the presence or absence of a target material based on the fluorescent light which is created. In some embodiments it is preferred if the majority of the fluorescent light occurs at a wavelength at least 50 nm longer the wavelength at which the majority of the emitted light 14, 24, 34, 44 or 54 occurs.

In preferred embodiments of this disclosure, the full width at half maximum (FWHM) of the spectrum of the emitted light 14, 24, 34, 44 or 54 preferably does not exceed 70 nm, and more preferably does not exceed 50 nm.

In preferred embodiments of this disclosure the wavelength at which the majority of the emitted light 14, 24, 34, 44 or 54 occurs is in the range from 300 nm to 1000 nm. In other preferred embodiments of this disclosure the wavelength at which the majority of the emitted light 14, 24, 34, 44 or 54 occurs is in the range from 300 nm to 600 nm. In certain embodiments of this disclosure it is preferred if the wavelength at which the majority of the emitted light 14, 24, 34, 44 or 54 occurs is in the range from 300 nm to about 400 or about 450 nm.

In embodiments of this disclosure the light emitting region 12, 22, 32, 42, 52 can optionally include at least one of a hole transport material, electron transport material and an organic electroluminescent material. The organic electroluminescent material may be an electrofluorescent material or an electrophosphorecent material.

In embodiments of this disclosure the light emitting region 12, 22, 32, 42 or 52 can further include at least one of a hole transport layer and an electron transport layer.

In embodiments of this disclosure the material 15, 25, 35, 45 or 55 can be any material that needs to have its presence or absence detected or have its concentration measured. Typically, this material is itself capable of fluorescence, i.e. is capable of producing luminescence at certain wavelengths characteristic of the said material when irradiated by light of a different wavelength. In embodiments when the material is not itself capable of fluorescence, the material can be mixed or functionalized with other fluorescent materials, to act as fluorescent markers, as is widely used in spectroscopic detection techniques for detecting chemical or biological agents. The fluorescence markers can alternatively be introduced in the container 49 or 59. The fluorescence wavelengths or intensity of the fluorescent marker is altered by the concentration of the material 15, 25, 35, 45 or 55. The material 15, 25, 35, 45 or 55 can be of any form, such as a gas, a liquid or a solid. The material 15, 25, 35, 45 or 55 can be intermixed or dissolved in one or more other substances, in which case the concentration of the material can be from about 10⁻⁶% to about 99% by weight or by volume of the mixture or solution.

In embodiments of this disclosure the light emitting device 1, 2, 3, 4 or, 5 is used in an apparatus for detecting the presence, absence or concentration of the material 15, 25, 35, 45 or 55. The apparatus can for example a sensing apparatus, such as a sensor for certain chemical or biochemical materials. In embodiments the material 15, 25, 35, 45 or 55 is the chemical or biochemical material be sensed. The sensing apparatus can be of any form such as, for example, a lab on a chip device. The apparatus can be used for any applications where the detection or sensing of the chemical or biochemical materials is required, such as, in gas sensing applications, air quality sensing applications, explosives detection applications, medical applications, industrial applications. Of course many other applications are also possible. In embodiments of this disclosure, the light emitting device 1, 2, 3, 4 or 5 is used as an optical excitation source in order to induce fluorescence from the material 15, 25, 35, 45 or 55 to be sensed.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

The above-described embodiments are intended to be examples only. Alterations, modifications and variations can be effected to the particular embodiments by those of skill in the art without departing from the scope, which is defined solely by the claims appended hereto.

What is claimed is:

1. A light emitting device comprising:
a first electrode;
a light emitting region including quantum dots; and
a second electrode;
wherein the device is used for producing fluorescence from a sample of interest.

2. The device of claim 1, wherein the said device is used in a sensing apparatus.

3. The device of claim 2, wherein the apparatus is used to detect the presence of a target material.

4. The device of claim 1, wherein the device is used in a lab-on-a-chip module

5. The device of claim 3, wherein the target material is a gas.

6. The device of claim 3, wherein the target material is a liquid.

7. The device of claim 3, wherein the target material is in a liquid

8. The device of claim 1, wherein the device further comprises at least one of a hole transport material and an electron transport material

9. The device of claim 8 wherein at least one of the hole transport material or the electron transport material is an organic material

10. The device of claim 1, wherein the quantum dots comprise a core-shell structure

11. The device of claim 1 wherein the light emitting device emits light with maximum intensity at a wavelength in the range of 300 nm-1000 nm

12. The device of claim 11 wherein the light emitting device emits light with maximum intensity at a wavelength in the range of 400 nm-700 nm

13. The device of claim 1 wherein the light emitting device emits light with maximum intensity at a wavelength different from the fluorescence maximum intensity wavelength of the sample of interest.

14. The device of claim 1 wherein the quantum dots comprise Cadmium Selenium (CdSe), Cadmium Sulfide (CdS), Zinc Selenium (ZnSe), Cadmium Sulfide (CdS), Cadmium Zinc (CdZn), Zinc Sulfide (ZnS), Indium Phosphide (InP), Indium Arsenide (InAs) or Cadmium Selenium Sulfide (CdSeS).

15. The device of claim 14, wherein the quantum dots have a diameter in the range 1-30 nm.

16. The device of claim 15, wherein the quantum dots have a diameter in the range 1-15 nm.
